(19) United States
(12) Patent Application Publication
(10) Pub. No.: US 2026/0231344 A1
(43) Pub. Date: Aug. 6, 2026

(54) QUICK RELEASE MECHANISM FOR CLAMSHELL HOUSING

(71) Applicant: ARRIS Enterprises LLC, Horsham, PA (US)

(72) Inventor: Jinwoo LEE, Souderton, PA (US)

(73) Assignee: ARRIS Enterprises LLC, Horsham, PA (US)

(21) Appl. No.: 19/531,296

(22) Filed: Feb. 5, 2026

Related U.S. Application Data
(60) Provisional application No. 63/754,477, filed on Feb. 5, 2025.

(51) Int. Cl. H05K 5/02

(52) U.S. Cl. CPC H05K 5/0226

(57) ABSTRACT

A clamshell housing for an electronic device in a Hybrid Fiber Coaxial (HFC) network having a hinge between a lid and a base, where the hinge may be selectively disassembled and reassembled without the use of tools.

### CROSS REFERENCE TO RELATED APPLICATIONS

The present application claims priority to U.S. Provisional App. No. 63/754,477 filed February 5, 2025, the contents of which are each incorporated herein by reference in their entirety.

### BACKGROUND

The subject matter of this application relates to enclosures for nodes, amplifiers, and other electronic equipment in a Hybrid Fiber Coaxial network.

Cable television (CATV) networks have evolved significantly since first being deployed as relatively simple systems that delivered video channels one-way from a content provider. These early systems included transmitters that assigned a number of CATV channels among several frequency bands, each of approximately 6 MHz, multiplexed those signals, and sent them to subscribers as an electrical signal through a network of coaxial transmission lines to cable modems or set-top boxes in subscribers homes. Early evolution of such systems permitted limited return communication from the subscribers back to the content provider either through telephone lines or a dedicated, small, low-frequency signal propagated onto the coaxial network.

Modern CATV networks differ from these early networks in several material respects. First, given the growth of content provided to customers over increasing distances, much of the coaxial transmission path has been replaced by fiber-optic lines, although the trunk lines and feeder cables to customer homes remain coaxial, and much of the content delivered to the provider for transmission is by an analog electrical signal that the provider must then convert to an optical signal for propagation onto the coaxial transmission grid. Nodes, located closer to the subscribers receive the optical signals from the transmitter and convert them to the electrical signals for delivery to the subscribers through the coaxial lines to the subscribers' homes. These coaxial lines include a large number of electrical devices such as amplifiers, taps to lines terminating at individual premises, etc. Such a network is commonly referred to as a Hybrid Fiber-Coax (HFC) system.

All of these electronic devices in the HFC network or “plant” are housed in enclosures that protect the electronic equipment housed inside. For example, nodes or amplifiers may be housed in enclosures that are mounted to telephone poles or other elevated locations, or in a sub-surface vault. These locations may be subjected to rain, ice, and temperature extremes that make it difficult to ensure that the equipment within the enclosure is protected from damage, and free from external moisture and debris, particularly when the enclosure is opened, and also may make it difficult to adequately dissipate heat from the electronic equipment in during periods of high temperatures. Thus, it often becomes necessary to repair the equipment inside the enclosure of a node, amplifier, or tap. Furthermore, it is often necessary to upgrade the equipment inside the enclosure.

A typical enclosure for electronic equipment in an HFC network is called a clamshell enclosure; the housing includes a hinged connection to one side, which allows it to open as would a clamshell, and furthermore the electronic equipment in the housing is included both within the lid itself, as well as the base against which the lid seals. When repairing or upgrading equipment within the enclosure, it is therefore sometimes helpful to disengage the hinged lid from the base, and re-engage it following service, but this is often difficult.

What is desired, therefore, is an improved clamshell enclosure for electronic equipment that facilitates the ease of disengaging and engaging the clamshell enclosure’s lid the enclosure’s base.

### BRIEF DESCRIPTION OF THE DRAWINGS

For a better understanding of the invention, and to show how the same may be carried into effect, reference will now be made, by way of example, to the accompanying drawings, in which:

FIG. 1 shows a perspective view of a clamshell housing having an improved hinge assembly between the enclosure’s lid and base.

FIG. 2 shows the clamshell housing of FIG. 1 opened, exposing the hinge assembly that connects the lid and the base.

FIG. 3 shows a cross section of the hinge assembly of FIGS. 1 and 2.

FIG. 4 shows an exploded view of the hinge assembly of FIGS. 1 and 2.

### DETAILED DESCRIPTION

As noted previously, a typical electronic enclosure for electronic equipment in an HFC network includes a clamshell housing that protects the equipment, and which has a hinged connection between a lid of the enclosure and the base of the enclosure. As also previously noted, during repair and/or upgrade of the equipment it is often required or at least helpful to disengage the hinge assembly so that the lid is completely disconnected from the base. This may be inconvenient, requiring separate tools, and also frequently producing a number of loose parts that together form the hinged connection e.g., bolts, nuts, etc.

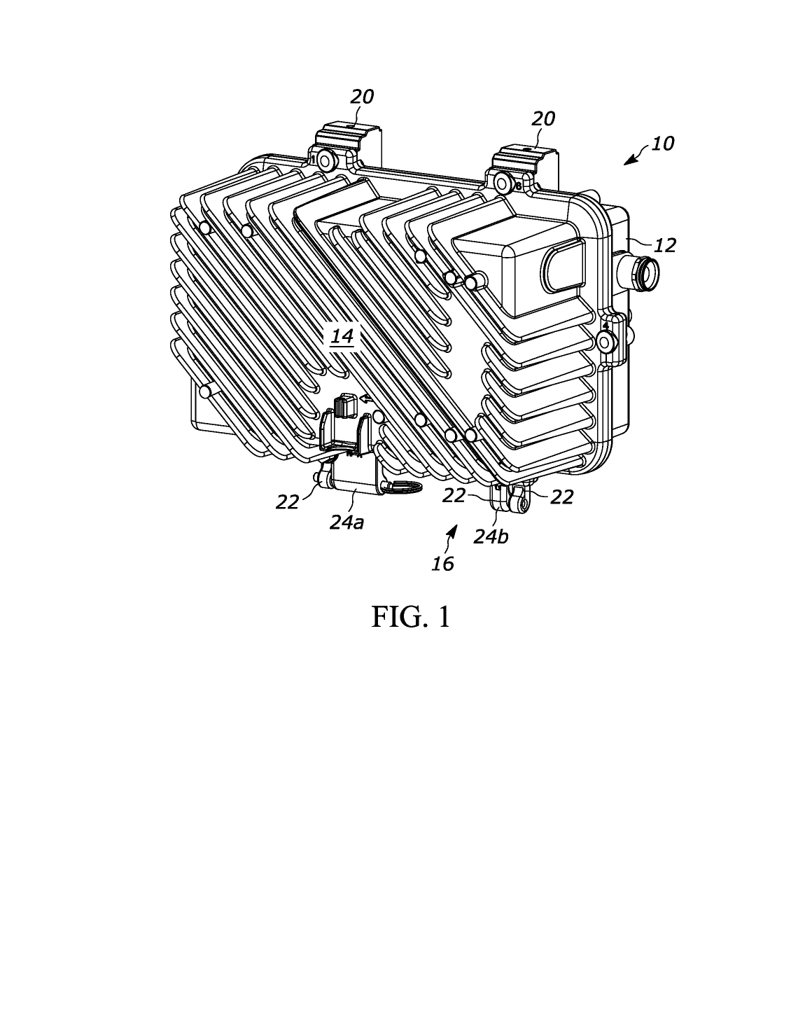

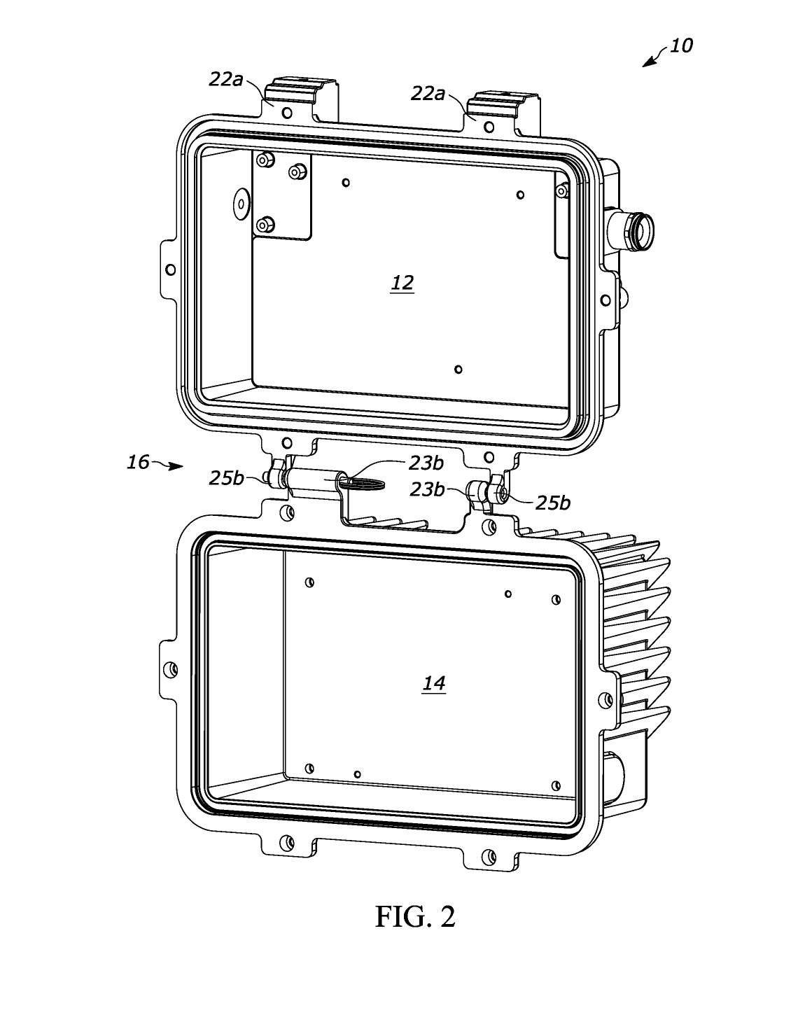

Disclosed in the present specification is a novel, improved clamshell enclosure that includes a hinge assembly that selectively engages the enclosure’s lid to the base in a hinged manner, and which may be disassembled and reassembled without tools, and without loose parts. Referring to FIGS. 1 and 2, for example, a clamshell housing 10 may comprise a base section 12 and a lid section 14 connected together by a hinge assembly 16. Both the base section 12 and the lid section 14 comprise receptacles within which electronic equipment, such as amplifiers, cables, etc. may be housed.

In the closed configuration, as shown in FIG. 1, the clamshell housing is preferably environmentally sealed to protect the electronic equipment housed therein, and therefore the base section and the lid section preferably have outer perimeters that press against each other when closed, and also may include a sealing gasket at this outer permitter. The clamshell housing 10 may also preferably include sealing members 20, 22 to secure the lid section 14 and base section 12 to each other when closed, via appropriate connections such as bolts, etc. The enclosure 10 includes sealing members 20 that seal the enclosure at an edge away from the hinge assembly 16, while sealing members 22 seal the enclosure at an edge proximate the hinge assembly 16. The hinge assembly 16 allows the housing 12 to be opened (FIG. 2) and closed (FIG. 1) in a predefined orientation so that when closed, after being opened, the two sections are properly sealed against each other.

When repairing or upgrading the electronic equipment within the enclosure 10, is it often necessary or at least helpful to disassemble the hinge assembly 16, separating the connection between the base section 12 and the lid section 14. In some circumstances, for example, a lid section 14 or a base section 12 may need to be replaced upgraded to a different version. Alternatively, repairs of existing equipment may be easier to perform if the lid section 14 and the base section 12 are separated. Prior art enclosures included hinge assemblies that were disassembled using specialized tools and into a relatively large number of loose parts such as nuts, bolts, etc. Conversely, the present specification discloses a tool-less hinge assembly that has no loose parts, and can be disassembled and reassembled in mere seconds.

Specifically, the enclosure 10 includes a hinge assembly 16 that pivotably interconnects the base section 12 and the lid section 14. In the embodiment shown in FIGS. 1 and 2, the hinge assembly 16 comprises a primary hinge 24a and a secondary hinge 24b laterally spaced apart from each other, though those of ordinary skill in the art will appreciate that other embodiments may use only a single such hinge. As noted previously, proximate the hinge assembly 16 are sealing members on each of the lid section 14 (reference numbers 22b) and the base section 12 (reference numbers 22a). The respective primary hinge 24a and secondary hinge 24b each pivotably connect one of the sealing members 22a to a sealing member 22b via respective cylindrical sleeves 23a and 25a, 23b and 25b. The primary hinge 24a comprises a plurality of components, described later, that may be selectively actuated when assembling/disassembling the clamshell housing’s hinged connection. The secondary hinge 24b comprises interlocking parts that may be separated/conjoined from each other manually, but only when primary hinge 24a is disjoined. In other words, the hinge assembly 16 is selectively assembled and disassembled via the primary hinge 24a; the secondary hinge 24b merely provides structural support for the hinge assembly 16 when assembled.

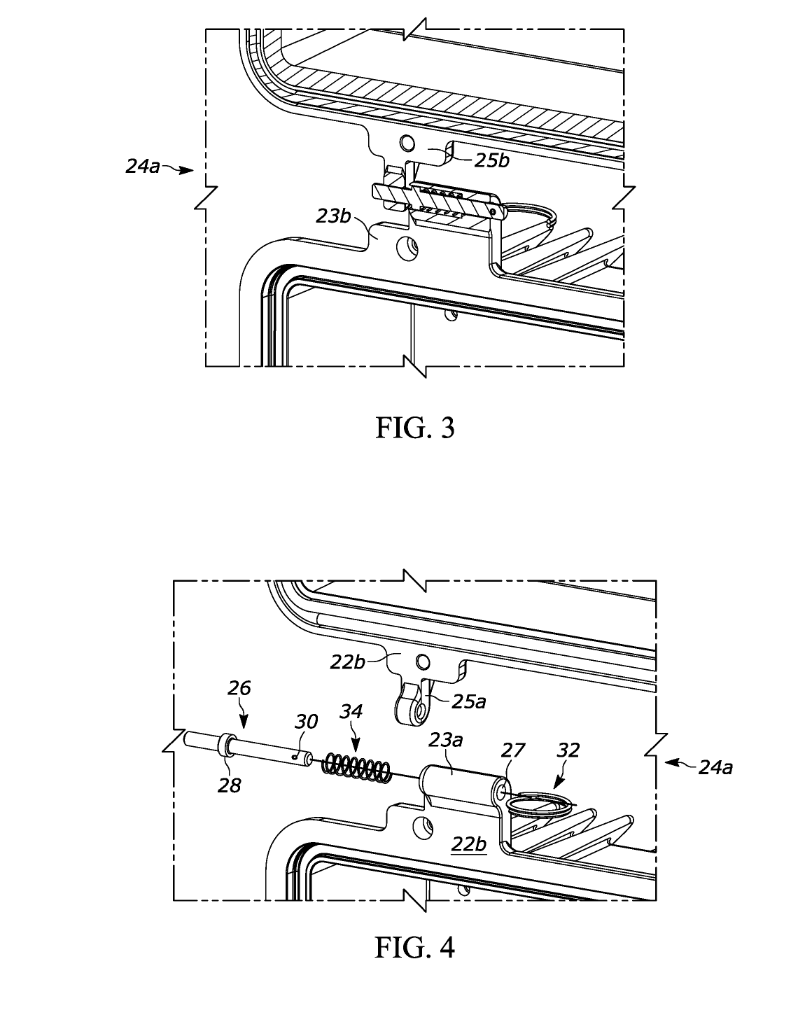

Referring to FIGS. 3 and 4, the primary hinge 24a is constructed from a minimal number of component pieces. First, the primary hinge 24a includes cylindrical sleeve members 23a, 25a that together form an interior passage 27 for a hinge pin 26; when inserted into the interior passage 27, the cylindrical sleeve members 23a, 25a can rotate relative to each other around the hinge pin 26 thereby allowing the hinged opening and closing movements of the clamshell housing 10. The hinge pin 26 comprises a generally cylindrical elongate member that is retained in the interior passage 27 at one end by an annular disc 28 surrounding the elongate member and sized to press (under spring action as described later) against a lateral interior surface of cylindrical sleeve member 25a to prevent the hinge pin’s removal from the interior passage 27.

Proximate the other end of the hinge pin 26 is a hole 30 into which a pull coil 32 is inserted. The pull coil 32 may in some embodiments be formed of a thin, flexible material, such as aluminium, copper, or other metal or plastic that, that when coiled, allows an end of the thin coil to be inserted into the hole and rotated one direction to lock in place. Those of ordinary skill in the art will appreciate, however, the pull coil may be substituted with any other device that allows a technician to grasp it and pull the hinge pin 27.

Surrounding the hinge pin 26 is a compression spring 34 that biases the distal end of hinge pin 26, opposite the pull coil 32, to a position that extends through the cylindrical sleeve member 25a, and in some embodiments the compression spring exerts a force on the annular disc 28, which is prevented from moving under this force by the lateral interior surface of cylindrical sleeve member 25a against which it presses. Preferably, the annular disc 28 and the hole 30 are separated from each other along the hinge pin 26 by a distance so that, with the hinge pin inserted into the interior passage and the pull coil 32 situated in the hole 30, the compression spring exerts this force. Those of ordinary skill in the art will appreciate however, that in alternate embodiments, the compression spring 34 may be in a relaxed state until the pull coil 32 is pulled.

In operation, when the lid section 14 needs to be removed from the base section 12, all a technician need do is pull the coil 32; this pulls the distal end of the hinge pin 26 from the cylindrical sleeve member 25a, against the force of the spring 34, which is compressed. At this point, the sleeve members 23a, 25a of the primary hinge 24a may be separated, after which the sleeve members 23b, 25b of the secondary hinge 24b may be separated, thereby disconnecting the lid section 14 from the base section 12. When the lid and base of the enclosure 10 needs to be reconnected, all technician needs to do is align the cylindrical sleeve members 23b, 25b to reassemble secondary hinge 24b, pull the coil 32 to allow cylindrical sleeves 23a, 25a to be aligned, then release the pull coil 32 to reassemble primary hinge 24a.

As can be seen by this procedure, the lid and base of the disclosed clamshell enclosure can easily be disconnected from each other, without specialized tools, and without creating any loose parts that might be lost and/or damaged.

It will be appreciated that the invention is not restricted to the particular embodiment that has been described, and that variations may be made therein without departing from the scope of the invention as defined in the appended claims, as interpreted in accordance with principles of prevailing law, including the doctrine of equivalents or any other principle that enlarges the enforceable scope of a claim beyond its literal scope. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. The word "comprise" or a derivative thereof, when used in a claim, is used in a nonexclusive sense that is not intended to exclude the presence of other elements or steps in a claimed structure or method.

1. A clamshell housing for an electronic device in a Hybrid Fiber Coaxial (HFC) network, comprising:
a lid and a base selectively and pivotably connectable to each other by a hinge comprising a first sleeve member and a second sleeve member, together defining an interior passage;
a hinge pin housed within the first sleeve member and having a distal end biased by a compression spring to engage with the second sleeve member; and
a pull member connected to the hinge pin and configured to allow the distal end of the hinge pin to disengage from the second sleeve member when pulled.

2. The clamshell housing of claim 1 where the pull member compresses the compression spring when pulled.

3. The clamshell housing of claim 1 where the spring surrounds the hinge pin.

4. The clamshell housing of claim 3 where the hinge pin includes an annular flange that compresses the compression spring when the pull member is pulled.
